(19) United States
(12) Patent Application Publication
(10) Pub. No.: US 2012/0068302 A1
(43) Pub. Date: Mar. 22, 2012

(54) ELECTRONIC DEVICE AND METHOD FOR DIRECT MOUNTING OF PASSIVE COMPONENTS

(75) Inventors: Stefan Beierke, Furth (DE); Johann Gross, Berglern (DE)

(73) Assignee: Texas Instruments Deutschland GmbH, Freising (DE)

(21) Appl. No.: 13/228,099

(22) Filed: Sep. 8, 2011

(30) Foreign Application Priority Data
Sep. 17, 2010 (DE) 10 2010 045 649.7

(51) Int. Cl. H01L 27/06; H01L 21/50; H01L 23/48

(52) U.S. Cl. 257/531; 257/773; 438/106; 257/E23.01; 257/E27.018; 257/E21.499

(57) ABSTRACT

An electronic device including a semiconductor die, which has a top surface that is configured to operate as a printed circuit board so as to provide connections for at least one passive component, in particular a passive surface mounted device (SMD).

### CROSS-REFERENCE TO RELATED APPLICATIONS

This patent application claims priority from German Patent Application No. 10 2010 045 649.7, filed Sep. 17, 2010, which is incorporated herein by reference in its entirety.

### FIELD OF THE INVENTION

The invention relates to an electronic device configured to operate as half duplex radio frequency transponder and to method for manufacturing the electronic device.

### BACKGROUND OF THE INVENTION

Radio frequency transponders may generally be divided into two groups: half duplex (HDX) transponders and full duplex (FDX) transponders. FDX transponders merely reflect a radio frequency signal sent by the reader. HDX transponders use the received radio frequency signal for charging an inner energy storage device, typically a capacitor. The energy in the capacitor is then used for actively sending a signal from the transponder to the reader. Therefore, HDX transponders need a relatively large capacitor for storing energy. Furthermore, HDX transponders use a coil as antenna. The coil can be considered as an inductor. The electronic circuits necessary for providing the required functionality as a transponder as well as the radio frequency front end are implemented as an integrated semiconductor circuit, i.e. in form of a chip. The chip consists of a package in which a semiconductor die is located. The die contains the integrated electronic circuitry. The package serves as a protection and as an interface between the very small contacts on the die and the rather large contact areas of a PCB to which the die is fixed. A typical assembly of an RFID transponder would then include a printed circuit board (PCB), the packaged die coupled to a PCB and some passive components as for example at least the antenna (inductor) and the buffer capacitors which are also coupled to the PCB. The relevant size of the die is usually referred to as the chip size and relates to the area of the top surface of the die. In a given technology (die manufacturing process), the chip area or die area defines the costs for the die. The larger the die, the more expensive is the manufacturing. In order to keep the total costs for an RFID transponder low, the chip area is minimized. The desire to minimize the chip area led, among other reasons, to a continued reduction of the minimum structure length. This is well known in the art. However, the price of an RFID transponder is still too high for many applications, as for example tagging of cheap mass products. It is therefore desirable to further reduce the costs of the devices.

### SUMMARY OF THE INVENTION

It is a general object of the invention to provide a method of manufacturing an electronic device for an RFID transponder and an electronic device.

In an aspect of the invention, there is an electronic device comprising a semiconductor die. The semiconductor die has a top surface that is configured to operate as a printed circuit board (PCB) with respect to connecting passive components to the semiconductor die. The top surface of the semiconductor die is configured to provide connections for at least one passive component, in particular a passive surface mounted device (SMD). In order to provide the connections (pads) for the passive components, the chip size of the semiconductor die and, in particular the area of top surface of the semiconductor die is increased. The size of the semiconductor die is then greater then size necessary for accommodating the electronic integrated circuitry required for the target application of the semiconductor die. Using the top surface of a semiconductor die as direct interface to passive components instead of using a separate PCB can substantially reduce the costs for manufacturing the device although the size of semiconductor die has to be increased.

In one aspect of the invention, there is an electronic device comprising a semiconductor die configured to operate as half duplex radio frequency transponder. There is at least a first capacitor and an inductor coil serving as antenna. The semiconductor die may comprise a metal layer on a top surface dimensioned to directly contact pads of the capacitor and the inductor coil. In order to provide enough area for the contact pads of the capacitor and the inductor coil, the top surface of the semiconductor is increased. In view of the general desire to reduce chip area, this aspect of the invention is counterintuitive. However, the total costs of the RFID transponder are decreased although the semiconductor die has larger dimensions. The reason for the cost reduction is a reduced complexity of the manufacturing steps, when passive components and semiconductor die are directly coupled instead of using a PCB.

According to an aspect of the invention, a semiconductor die is provided which has a top surface that is configured to provide the functionality of a PCB. The size of the die is adapted in order to provide the pads, which are usually arranged on the PCB. The electronic device in which the semiconductor die is used has a reduced total size with respect to electronic devices using PCB. The manufacturing of the RFID device is then cheaper than with a PCB as less process steps are required and fewer components are used. Furthermore, if the electronic device is an RFID transponder, in particular a HDX RFID transponder, the performance can be improved. This is due to the fact the other components, for example the inductor coil, can have large dimensions.

In an embodiment of the invention, the electronic device may be an RFID transponder, in particular a 12 mm HDX glass transponder.

The metal layer of the semiconductor die can be configured to provide at least two pads in the top metal layer of the semiconductor die for the inductor. Each of the at least two pads may have at least 200 μm length and 400 μm width. These dimensions correspond to typical dimensions of surface mounted devices. If the metal pads in the top surface are increased so as to accommodate these dimensions, it is possible to directly couple the standard inductor coils to the semiconductor die.

The pads in the top metal layer of the semiconductor die for the inductor can be configured to be welded to the contact wires of the inductor. This is a way of connecting the inductor coil which provides high stability. The metal layer on the semiconductor die should then be configured accordingly.

Furthermore, at least two contact pads for the capacitor may be provided in the top metal layer of the semiconductor die. Each pad may then have at least 350 μm length and 500 μm width. With these dimensions it is possible to accommodate a capacitor with a capacitance that is sufficient to meet the typical requirements of a HDX transponder.

The pads in the top metal layer of the semiconductor die for the capacitor may then be configured to be glued to the contact pads of the capacitor. This is an appropriate method of contacting the capacitor for most conditions under which the RFID transponder may be used.

The capacitor may have a capacitance of 0.22 μF and the inductor coil may have an inductance of 6.7 mH.

The semiconductor die may have a width of 1 mm and a length of 1.5 mm and a thickness of 0.8 mm. In another embodiment, the semiconductor die may have a width of 2.2 mm and a length of 2.5 mm and a thickness of 0.8 mm.

In an aspect of the invention, the area of the top surface of the semiconductor die may generally be increased to more than one square millimeter in order be able to connect the passive components without using a separate PCB board.

The metal layer used for building the pads on the top surface can be an upper metal layer of the interconnection layer of the semiconductor die. The metal layer can for example be the fourth interconnection metal layer above an integrated electronic circuitry in the semiconductor die.

The invention provides a method for manufacturing a half duplex radio frequency transponder. Accordingly, a die including an integrated electronic circuit to be operated in the half duplex transponder may be manufactured. Areas of an upper metal layer of the semiconductor die may be defined so as to use these areas as pads. These pads are configured and dimensioned for being connected to contacts of at least a passive capacitor and a passive inductor coil. The dimensions of the top surface of the semiconductor die are increased with respect to the required area for the integrated circuitry for the target application, as for example a RFID HDX application. Finally, the semiconductor die is manufactured in accordance with the required dimensions. Furthermore, the electronic device, as for example the RFID transponder is manufactured using the semiconductor die. The top surface of the die provides the connections for the passive components. The passive components, as for example the capacitor or the inductor coil may then be coupled to semiconductor die in a pick and place step. The contacts of the passive components may be (directly) soldered or welded to the top surface of the semiconductor die. If Nickel-Gold (NiAu) is used, welding may not be used. A passive component, as for example the inductor coil may be welded to pads on the top surface of the die. Another passive component, as for example the capacitor, may be glued to the pads on the top surface of the semiconductor die. In order to connect at least one of the passive components, Nickel-Gold (NiAu) bumps may be used. A further solder reflow process can then be used to build the interconnection. The usage of NiAu bumps allows the coils to be connected as well as to use a simple solder reflow process to assemble passive elements directly on the semiconductor die.

### BRIEF DESCRIPTION OF DRAWINGS

Further aspects of the invention will appear from the appending claims and from the following detailed description given with reference to the appending drawings. Further aspects of the invention will ensue from the following description of preferred embodiments of the invention with reference to the accompanying drawings, wherein;

FIG. 1 shows a simplified schematic of an embodiment of the invention;

FIG. 2 shows a simplified and schematic top view on a first embodiment of a semiconductor die manufactured according to aspects of the invention;

FIG. 3 shows a flow chart of a method according to aspects of the invention; and

FIG. 4 shows a simplified and schematic top view on a second embodiment of a semiconductor die manufactured according to aspects of the invention.

### DETAILED DESCRIPTION OF AN EXAMPLE EMBODIMENT

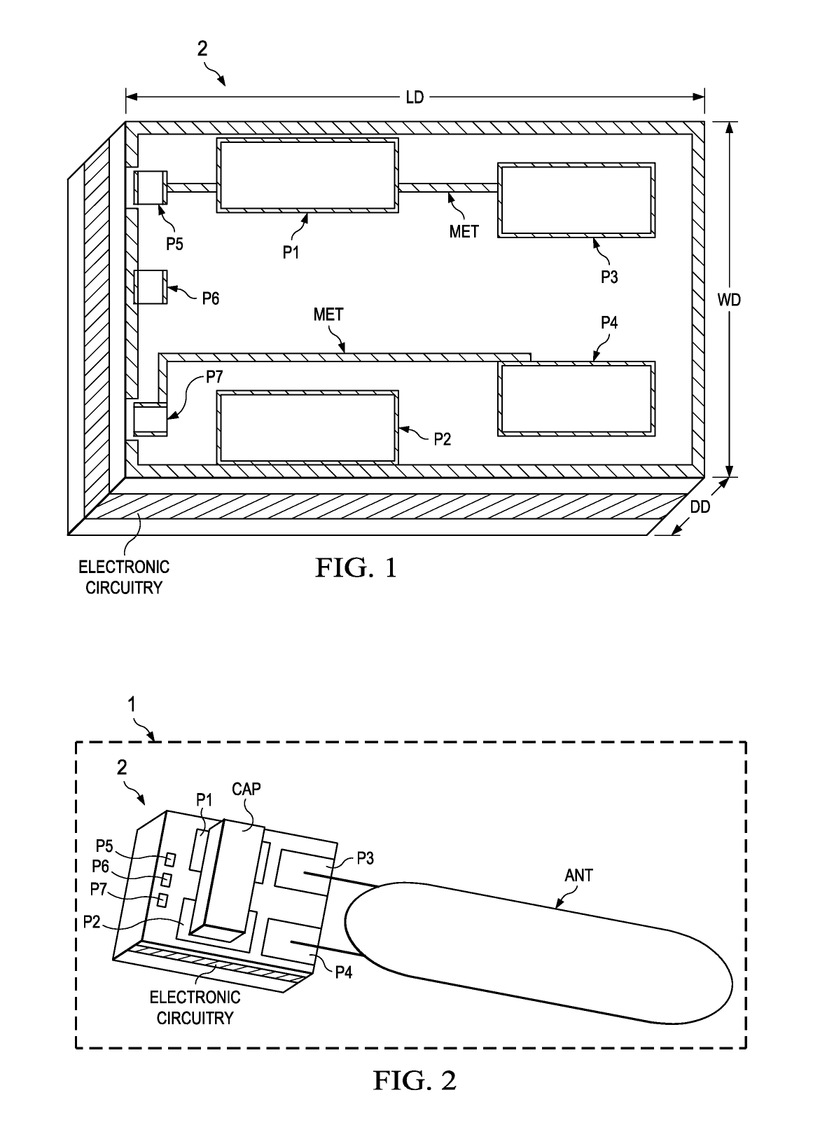

FIG. 1 shows a simplified schematic view of a semiconductor die 2 manufactured according to aspects of the invention. The upper surface has pads P1 and P2 of an upper metal layer for connecting a capacitor (not shown), in particular a surface mounted capacitor. There are also pads P3 and P4 of the upper metal layer for connecting an inductor coil (not shown). There are further pads P5, P6 and P7. These pads provide connections through VIAs (not shown) to the electronic circuitry which is covered by the upper surface. The electronic circuitry may contain analog and digital components for an HDX RFID transponder. Pads P1, P3 and P5 are connected by a metal wire MET. Also pads P4 and P7 are connected by a metal wire MET. Further connections for the other pads may be provided by lower metal layers which are not visible here. The width of the die is WD. The length is LD and the thickness is DD. WD by LD may be larger than one square millimeter. WD may be 1.5 mm, LD may be 1 mm. DD may be 0.8 mm. Alternatively, WD may be 2.2 mm, LD may be 2.5 mm. DD may be 0.8 mm.

FIG. 2 shows an electronic device 1 according to an embodiment of the invention. In this embodiment, electronic device is an RFID HDX transponder. There is an inductor coil ANT and a capacitor CAP. The inductor coil ANT is directly coupled to pads P3 and P4 of the semiconductor die 2. The connection may be made by welding. The capacitor CAP is connected to pads P1 and P2 of the semiconductor die 2. There are further pads P5, P6 and P7 which are connected through VIAs to the integrated electronic circuitry ELEC inside the semiconductor die. The inductor coil ANT is configured to operate as an antenna for the electronic device 1, which is a HDX RFID transponder in this embodiment. The capacitor CAP and the inductor coil ANT are directly connected to the pads P1, P2 and P3, P4, respectively. The top surface of the semiconductor die 2 is arranged as shown in FIG. 1. The top surface of the die is configured to provide the connectivity of a PCB. A PCB is therefore not necessary anymore.

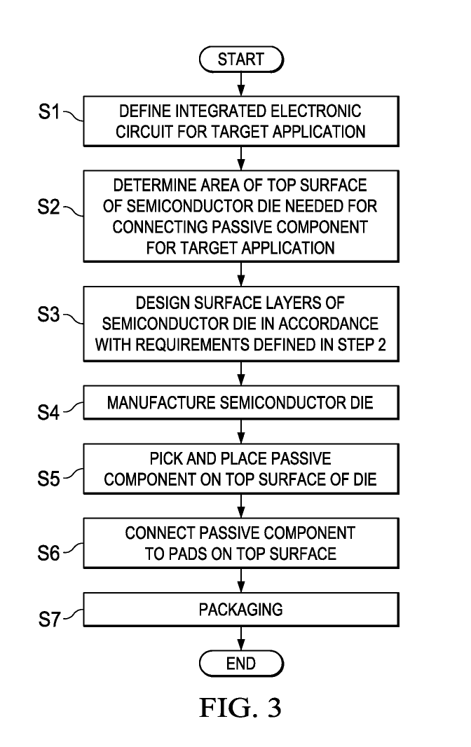

FIG. 3 shows a flow chart of a method according to aspects of the invention. In step S1 the integrated circuitry required for a target application of the semiconductor die is defined. The chip size of the semiconductor die required only for the integrated electronic circuit can then be determined. However, the actual size (width and length) of the top surface of the die is determined in step S2 in accordance with the needed pads for directly connecting the passive components to the top surface of the semiconductor die. In step S3, the surface layers are designed in order to arrange the pads on the top surface as required by at least on passive component. In this embodiment, at least one passive component is a surface mounted device (SMD). In step S4, the semiconductor die is manufactured. This is done in accordance with process and technology available or needed for the target application. The at least one passive component is then placed on the top surface of the semiconductor die in step S5. Step S5 can be a pick and place procedure for passive electronic components. Finally, the at least one passive component is connected (for example soldered, glued or welded) to the pads on the top surface of the semiconductor die in step S6. In order to connect at least one of the passive components, Nickel-Gold (NiAu) bumps may be used in step S6. A further solder reflow process can then be used to form the interconnection. The usage of NiAu bumps allows the coils to be connected as well as to use a simple solder reflow process to assemble passive elements directly on the semiconductor die. In step S7, the electronic device may be packaged.

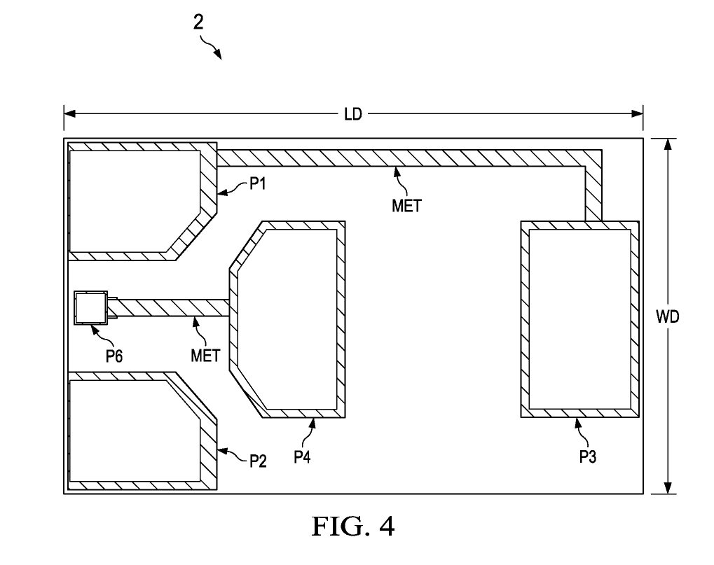

FIG. 4 shows a simplified and schematic top view on a second embodiment of a semiconductor die manufactured according to aspects of the invention. The main aspects of this embodiment are similar to those of the embodiment shown in FIG. 1. However, the pads P1, P2, P3 and P4 are rearranged and the dimensions of this embodiment are changed. P3 and P4 are the pads for accommodating the contacts of an inductor. The pads P3 and P4 are turned and the size was increased. This improves the possibility to weld these contacts. The pad openings for the welding pads P3 and P4 are also shifted to the left. It is particularly useful if the pads are in the same position and have the same size as those of a normal PCB design. The present invention makes it possible to use the same dimensions as for PCB layouts. The chip size is substantially increased in order to accommodate the contacts of the components to be connected to the top surface of the die. WD may be 2.2 mm, LD may be 2.5 mm. DD may be 0.8 mm. Also the pads P1, P2 for the capacitor are increased and moved to the left side. An electronic device would then look substantially similar to the embodiment shown in FIG. 2, but the inductor ANT would be turned by 90° with respect to the longitudinal axis of the capacitor CAP. This embodiment is useful for welding of the contacts.

Although the invention has been described in detail, it should be understood that various changes, substitutions and alterations can be made thereto without departing from the spirit and scope of the invention as defined by the appended claims.

1. An electronic device comprising a semiconductor die, which has a top surface that is configured to operate as a printed circuit board so as to provide connections for at least one passive component.

2. The electronic device according to claim 1, wherein the passive component is a passive surface mounted device (SMD).

3. The electronic device according to claim 1, being further configured to operate as half duplex radio frequency transponder; wherein the electronic device further comprises:
at least a first capacitor and an inductor coil serving as antenna; and
wherein the semiconductor die comprises a metal layer on a top surface dimensioned to directly contact the capacitor and the inductor coil.

4. The electronic device according to claim 1, wherein a metal layer of the semiconductor die is configured to provide at least two pads in the top metal layer of the semiconductor die for the inductor each pad having at least 200 μm length and 400 μm width.

5. The electronic device according to claim 4, wherein the pads in the top metal layer of the semiconductor die for the inductor are configured to be welded to the contact wires of the inductor coil.

6. The electronic device according to claim 3, further comprising at least two contact pads for the capacitor in the top metal layer of the semiconductor die each pad having at least 350 μm length and 500 μm width.

7. The electronic device according to claim 6, wherein the pads in the top metal layer of the semiconductor die for the capacitor are configured to be glued to the contact pads of the capacitor.

8. The electronic device according to claim 6, further comprising wherein the capacitor has a capacitance of 0.22 μF and the inductor has an inductance of 6.7 mH.

9. The electronic device according to claim 8, wherein the semiconductor die has a width of 2.2 mm and a length of 2.5 mm and a thickness of 0.8 mm.

10. The electronic device according to claim 1, wherein top surface configured to operate as a printed circuit boad is a metal layer which is a fourth interconnection metal layer above an integrated electronic circuitry in the semiconductor die.

11. The electronic device according to claim 2, wherein top surface configured to operate as a printed circuit boad is a metal layer which is a fourth interconnection metal layer above an integrated electronic circuitry in the semiconductor die.

12. The electronic device according to claim 3, wherein top surface configured to operate as a printed circuit boad is a metal layer which is a fourth interconnection metal layer above an integrated electronic circuitry in the semiconductor die.

13. The electronic device according to claim 10, wherein a metal layer of the semiconductor die is configured to provide at least two pads in the top metal layer of the semiconductor die for the inductor each pad having at least 200 μm length and 400 μm width.

14. The electronic device according to claim 10, wherein the pads in the top metal layer of the semiconductor die for the inductor are configured to be welded to the contact wires of the inductor coil.

15. A method for manufacturing a half duplex radio frequency transponder, the method comprising:
manufacturing a die including an integrated electronic circuit to be operated in the half duplex transponder;
defining areas of an upper metal layer of the semiconductor die in order to operate as pads for being connected to contacts of at least one of a passive capacitor and a passive inductor;
manufacturing the semiconductor die in accordance with the defined metal areas.

16. A method for forming an electronic circuit comprising:
forming an integrated circuit having a metal top layer configured for accepting a passive component; and
attaching the passive component directly to the metal top layer to form a circuit.
